(19) United States
(12) Patent Application Publication
(10) Pub. No.: US 2025/0234658 A1
(43) Pub. Date: Jul. 17, 2025

(54) BONDED WIRE FOR INTERCONNECTING SOLAR CELLS

(71) Applicant: Maxeon Solar Pte. Ltd., Singapore (SG)

(72) Inventors: Richard H. SEWELL, Los Altos, CA (US); Paul Loscutoff, Castro Valley, CA (US); Colin Martin, Soquel, CA (US); Matthieu Reich, San Jose, CA (US)

(73) Assignee: MAXEON SOLAR PTE. LTD., Singapore (SG)

(21) Appl. No.: 18/411,556

(22) Filed: Jan. 12, 2024

(51) Int. Cl. H01L 31/05; H01L 31/18

(52) U.S. Cl. CPC H10F 19/908; H10F 71/1375

(57) ABSTRACT

A string of solar cells interconnected by metal wires. The bonded metal interconnect wires having a cross-sectional area with a head and shoulder shape or with a curved dome shape. An apparatus for manufacturing a string of solar cells. The apparatus bonds metal interconnect wires to solar cells and results in wires having a cross-sectional area with a head and shoulder shape or with a curved dome shape.

### FIELD OF THE INVENTION

The invention relates generally to solar cell modules or panels in which the solar cells have wire-based metallization.

### BACKGROUND

Alternate sources of energy are needed to satisfy ever increasing world-wide energy demands. Solar energy resources are sufficient in many geographical regions to satisfy such demands, in part, by provision of electric power generated with solar (e.g., photovoltaic) cells.

Generally, solar radiation impinging on the surface of, and entering into, the substrate of a solar cell creates electron and hole pairs in the bulk of the substrate. The electron and hole pairs migrate to p-doped and n-doped regions in the substrate, thereby creating a voltage differential between the doped regions. The doped regions are connected to conductive regions on the solar cell to direct an electrical current from the cell to an external circuit. When solar cells are combined in an array such as a solar cell module, the electrical energy collected from all of the solar cells can be combined in series and parallel arrangements to provide power with a desired voltage and current.

### SUMMARY

This specification discloses a string of silicon solar cells interconnected by wires that also serve as metal contacts to the solar cells.

This specification discloses a string of solar cells comprising at least a first and second solar cells electrically connected in series. Each solar cell in the string comprises a silicon semiconductor substrate, an n-type doped region, and a p-type doped region. In some embodiments the n-type doped region and the p-type doped region may be diffusion regions within the silicon semiconductor substrate. In some embodiments, each solar cell in the string may be a back contact solar cell where the n-type doped region and the p-type doped region are both on the back side of the solar cell, where the back side of the solar cell is the side facing away from the sun. In some embodiments, each solar cell may have a plurality of n-type doped regions and a plurality of p-type doped regions.

This specification discloses a string of solar cells comprising a conductive wire interconnecting the first and second solar cells in the string. The conductive wire comprises a metal. The conductive wire may comprise copper or a copper alloy. The conductive wire may comprise aluminum or an aluminum alloy. The conductive wire is bonded to the first and second solar cells so that the conductive wire is in contact with the n-type doped region of the first solar cell and in contact with the p-type doped region of the second solar cell. Thus, the metal conductive wire serves as a metal contact for both the first and second solar cell.

The bonded conductive wire at a point of contact with a doped region, e.g. the n-type doped or p-type doped region, of the first solar cell has a cross-sectional area perpendicular to the length of the conductive wire. In some embodiments, the perimeter of this cross-sectional area has an inflection point, i.e. a point where the concavity of the perimeter changes from concave up to concave down or vice versa. In some embodiments, the bonded conductive wire at a point of contact with a doped region, e.g. the n-type doped or p-type doped region, of the second solar cell has a second cross-sectional area perpendicular to the length of the conductive wire. The perimeter of this second cross-sectional area has an inflection point.

In some embodiments, the bonded conductive wire has substantially the same cross-sectional shape along a majority of the length of the first solar cell. In some embodiments, the bonded conductive wire has a cross-sectional area with a head and shoulder shape. In some embodiments, the perimeter of the cross-sectional area of the bonded wire has a footprint length greater than 200 microns and less than 500 microns. In some embodiments, a line from the footprint length to the inflection point on the perimeter delineates a shoulder portion of the cross-sectional area. The shoulder portion has a side opposite the footprint length that is substantially flat and parallel to the footprint length. In some embodiments, the cross-sectional area of the bonded wire has a width that is greater than the footprint length.

In some embodiments, the first and second solar cells each have a passivation layer coating the silicon semiconductor substrate. In some embodiments, the passivation layer coats the back side of each solar cell and the passivation layer has holes aligned with the doped regions of the solar cell. In some embodiments, the bonded conductive wire contacts doped regions, e.g. n-type doped or p-type doped regions, of a solar cell through a hole in the passivation layer. In some embodiments, the passivation layer has two or more rows of holes aligned with a single doped region.

In some embodiments, this specification discloses a string of solar cells comprising at least a first and second back contact solar cells electrically connected in series. Each back contact solar cell comprises a silicon semiconductor substrate, an n-type doped region, a p-type doped region, and a passivation layer comprising a hole. The string of solar cells comprises an aluminum conductive wire in contact with the n-type doped region of the first solar cell, where contact is made through the hole in the passivation layer of the first solar cell. The conductive wire is also in contact with the p-type doped region of the second solar cell, where contact is made through the hole in the passivation layer of the second solar cell. The conductive wire at a point of contact with the n-type doped region of the first solar cell has a cross-sectional area perpendicular to a length of the conductive wire where the perimeter of the cross-sectional area has at least four inflection points. In some embodiments, the conductive wire at a point of contact with the p-type doped region of the second solar cell has a second cross-sectional area perpendicular to the length of the conductive wire, where the perimeter of the second cross-sectional area has at least 4 inflection points. In some embodiments, the perimeter of the cross-sectional area has a footprint length and a first line from the footprint length to one of the four inflection points on the perimeter delineates a first shoulder portion of the cross-sectional area, and a second line from the footprint length to another of the four inflection points on the perimeter delineates a second shoulder portion of the cross-sectional area. Each shoulder portion has a side opposite the footprint length that is substantially flat and parallel to the footprint length.

In some embodiments, the bonded conductive wire has a dome shape with no shoulders. The cross-sectional area perpendicular to the length of the dome-shaped wire has a substantially straight portion adjacent to solar cell and a curved portion opposite the substantially straight portion. In some embodiments, the perimeter of the dome shaped wire has a curved portion located at the midline of the cross-sectional area and opposite the substantially straight portion.

This specification discloses a method of fabricating a string of solar cells. The method comprises positioning at least two solar cells adjacent to one another such that a doped region of a first solar cell is aligned with a doped region of the second solar cell, providing a roller comprising a groove with sloped walls, placing a wire within the groove, bonding the wire within the groove to the doped region of the first solar cell by applying a force onto the roller, bonding the wire within the groove to the doped region of the second solar cell, where the dimensions of the groove is configured so that when the force is applied, the perimeter of a cross-sectional area of the bonded wire either has an inflection point or has a substantially straight portion adjacent to first solar cell and a curved portion opposite the substantially straight portion.

In some embodiments, the method includes rolling the roller along the first and second solar cells to bond the wire to the solar cells. In some embodiments, a downward force of 20 N to 80 N per wire is applied to the roller to bond the wire to the solar cells. In some embodiments, heat is applied to the roller so that the temperature of the roller is between 300° C. to 500° C. while bonding the wire to the solar cells. In some embodiments, the method of fabricating a string of solar cells uses the roller having a groove to deform the wire when bonding the wire so that the cross-sectional shape of the wire is deformed to having a head and shoulder shape. In some embodiments, the wire is deformed to having a dome shape.

In some embodiments, the method includes placing a plurality of wire within a plurality of grooves of a roller to simultaneously bond the plurality of wires to a plurality of doped regions on a first solar cell and to a plurality of doped regions on a second solar cell.

In some embodiments, this specification discloses a method of fabricating a string of back contact solar cells. Each back contact solar cell has a silicon substrate, a n-type doped diffusion region within the silicon substrate, and a n-type doped diffusion region within the silicon substrate. The n-type doped and p-type doped regions are located on the back side of the silicon substrate. Each solar cell has a passivation layer on the back side of the silicon substrate. The passivation layer has holes aligned with the doped diffusion regions of the solar cell. The method comprises positioning solar cells adjacent to one another such that a n-type doped region of one solar cell is aligned with a p-type doped region of an adjacent solar cell. The method comprises using a roller comprising a plurality of grooves, each groove optionally having sloped walls. The method comprises aligning wires with the doped regions of a solar cell using the grooves of the roller. The method comprises using downward force and heat on the roller to bond the wires within the grooves to the doped region of a first solar cell and then to bond the wires within the grooves to the doped region of the second solar cell. The dimensions of the groove are configured so that when the force is applied, the perimeter of a cross-sectional area of the bonded wire has four inflection points and cross-sectional area has a head and shoulder shape.

### BRIEF DESCRIPTION OF THE DRAWINGS

The figures described below depict various aspects of the system and methods disclosed herein. Each figure depicts an embodiment of a particular aspect of the disclosed system and methods, and that each of the figures is intended to accord with a possible embodiment thereof. Further, wherever possible, the following description refers to the reference numerals included in the following figures, in which features depicted in multiple figures are designated with consistent reference numerals.

FIG. 1 shows a plan view of the back side of a solar cell.

FIG. 2 shows a plan view of two interconnected solar cells.

FIG. 3 shows a plan view of four interconnected solar cells.

FIG. 4 shows a plan view of four interconnected solar cells.

FIG. 5 shows a side view of the roller apparatus.

FIG. 6 shows a cross-sectional view of the roller in the apparatus of FIG. 5.

FIG. 7A shows a cross-sectional view of the wire, roller, and solar cell where no downward force is applied to the roller and FIG. 7B shows a cross-sectional view of the wire, roller, and solar cell with downward force applied to the roller.

FIGS. 8A, 8B, 8C, and 8D show cross-sectional views of a wire bonded to a solar cell.

FIG. 9 is a graph of measurements taken of bonded wires subjected to different bonding conditions.

### DETAILED DESCRIPTION

The following detailed description should be read with reference to the drawings, in which identical reference numbers refer to like elements throughout the different figures. The drawings, which are not necessarily to scale, depict selective embodiments and are not intended to limit the scope of the invention. The detailed description illustrates by way of example, not by way of limitation, the principles of the invention. This description will clearly enable one skilled in the art to make and use the invention, and describes several embodiments, adaptations, variations, alternatives and uses of the invention, including what is presently believed to be the best mode of carrying out the invention.

As used in this specification and the appended claims, the singular forms “a,” “an,” and “the” include plural referents unless the context clearly indicates otherwise. Also, the term “parallel” is intended to mean “substantially parallel” and to encompass minor deviations from parallel geometries. The term “perpendicular” is intended to mean “perpendicular or substantially perpendicular” and to encompass minor deviations from perpendicular geometries rather than to require that any perpendicular arrangement described herein be exactly perpendicular. The term “square” is intended to mean “square or substantially square” and to encompass minor deviations from square shapes, for example substantially square shapes having chamfered (e.g., rounded or otherwise truncated) corners. The term “rectangular” is intended to mean “rectangular or substantially rectangular” and to encompass minor deviations from rectangular shapes, for example substantially rectangular shapes having chamfered (e.g., rounded or otherwise truncated) corners or may have non-linear edges. The term “identical” is intended to mean “identical or substantially identical” and to encompass minor deviations in shape, dimensions, structure, composition, or configuration, for example.

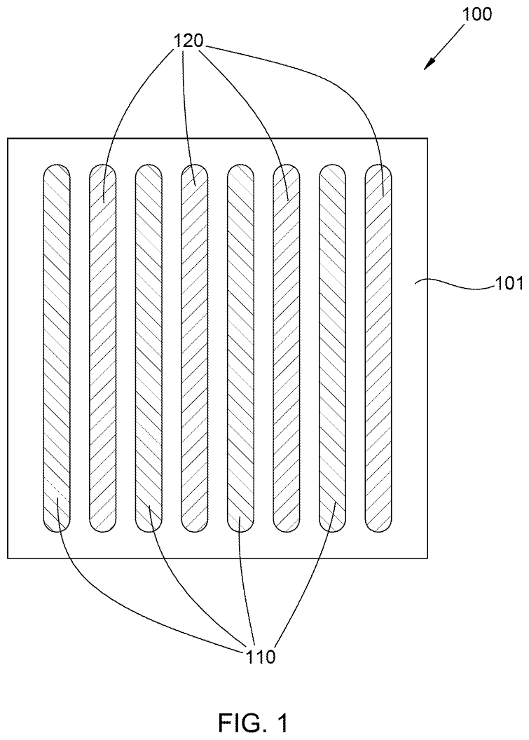

Solar cells comprise a silicon substrate having a front (sunny side) surface and a back (shaded side) surface. The silicon substrate may be a p-type silicon semiconductor substate, an n-type silicon semiconductor substrate, or an undoped silicon semiconductor substrate. The silicon substrate may be crystalline silicon or polycrystalline silicon. FIG. 1 illustrates the rear surface of a back contact solar cell 100. The back surface of silicon substrate 101 has a plurality of p-type 110 and n-type 120 doped diffusion regions. Each p-type 110 and n-type 120 doped diffusion region has a finger-like shape. Other shapes for the diffusion region are possible. The differently doped regions are interdigitated with one another forming an interdigitated back contact solar cell. Metal placed on the back surface of the silicon substrate in contact with the doped semiconductor regions forms metal contacts. Metal placed in contact with the n-type region becomes a negative contact. Metal placed in contact with the p-type region becomes a positive contact. When light shines on the front surface of the solar cell, electron-hole pairs are generated within the silicon substrate 101 by the light absorbed. The electron-hole pairs are split, and individual electrons and holes may be collected at the metal contacts on the back surface of the solar cell. Although FIG. 1 illustrates eight doped regions in the silicon substrate, many more doped regions in the silicon substrate may exist.

A string of solar cells is two or more solar cells connected together electrically in series. Solar cells may be connected together electrically in series for various reasons, e.g. to increase the voltage across the string. Strings of solar cells may themselves be electrically connected to make a solar panel. Solar cells are connected in series when the negative contact of one solar cell is connected to the positive contact of a neighboring solar cell or when the positive contact of one solar cell is connected to the negative contact of a neighboring solar cell. In the examples described in this specification, solar cells are connected in series using conductive metal wires that also serve as metal contacts.

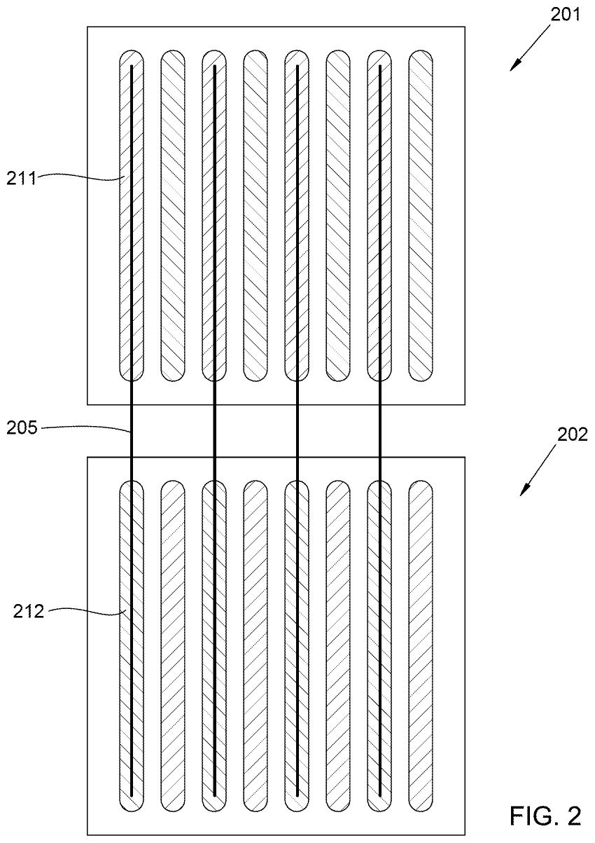

In FIG. 2, solar cells 201 and 202 are electrically connected in series by conductive metal wires 205. Metal wire 205 is placed in contact with the n-type doped diffusion region 211 of solar cell 201 thereby serving as a negative contact for solar cell 201. Metal wire 205 is also placed in contact with the p-type doped diffusion region 212 of solar cell 202 thereby also serving as a positive contact for solar cell 202. Therefore, a single metal wire serves as a metal contact for two solar cells and also interconnects the solar cells. Additional wires may be placed on solar cells 201 and 202 in a similar manner to connect the n-type doped region of solar cell 201 with the p-type doped region of solar cell 202.

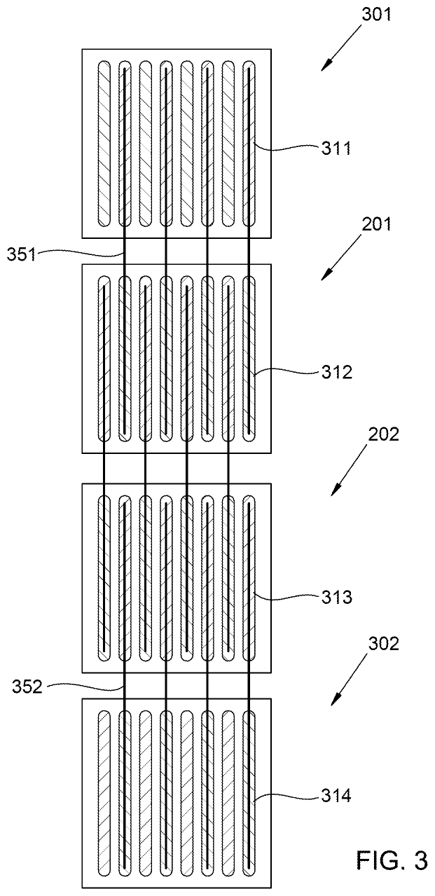

FIG. 3 illustrates four solar cells connected in series. The middle two solar cells (201, 202) are connected in the same way as in FIG. 2. In FIG. 3, solar cell 201 is further connected in series to solar cell 301. The p-type diffusion region 312 of solar cell 201 is connected to the n-type diffusion region 311 of solar cell 301 by metal wire 351. Additional wires 351 connect solar cells 201 and 301 in a similar manner. In addition, solar cell 202 is further connected in series to solar cell 302. The n-type diffusion region 313 of solar cell 202 is connected to the p-type diffusion region 314 of solar cell 302 by metal wire 352. Addition wires 352 connect solar cells 202 and 302 in a similar manner.

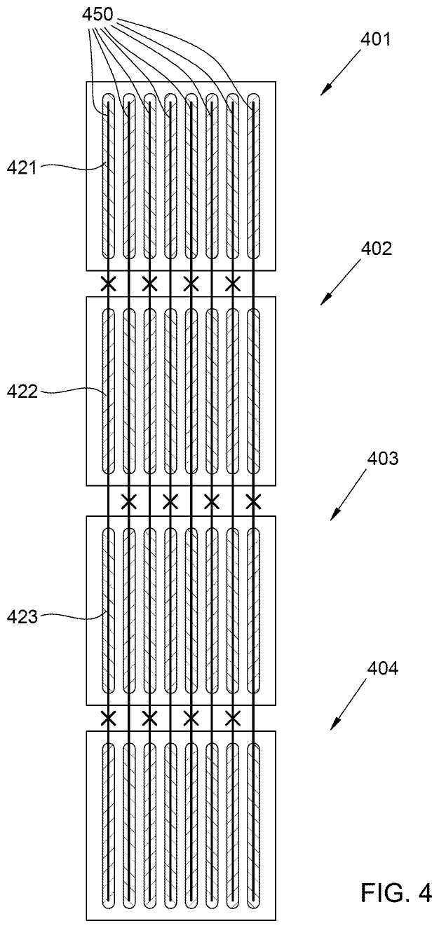

FIG. 4 illustrates an intermediate step in the process of connecting solar cells in series using wires. Solar cells 401, 402, 403, and 404 are arranged in a line so that the doped regions of one solar cell align with the doped regions of the other type in adjacent solar cells. For example, n-type doped region 422 of solar cell 402 is aligned with p-type doped region 421 of adjacent solar cell 401 and with p-type doped region 423 of adjacent solar cell 403. After the solar cells are so arranged, metal wires 450 are bonded to the doped regions of the solar cells using the roller apparatus discussed below. The bonded metal wires connect a doped region of one solar cell with a doped region of another type in an adjacent solar cell as shown in FIG. 4. After bonding the wires to the doped regions, alternate wires between solar cells are cut, i.e. at the spots marked “X” in FIG. 4. These cuts sever unwanted connections between solar cells. The remaining wire connections between solar cells connect the solar cells in series.

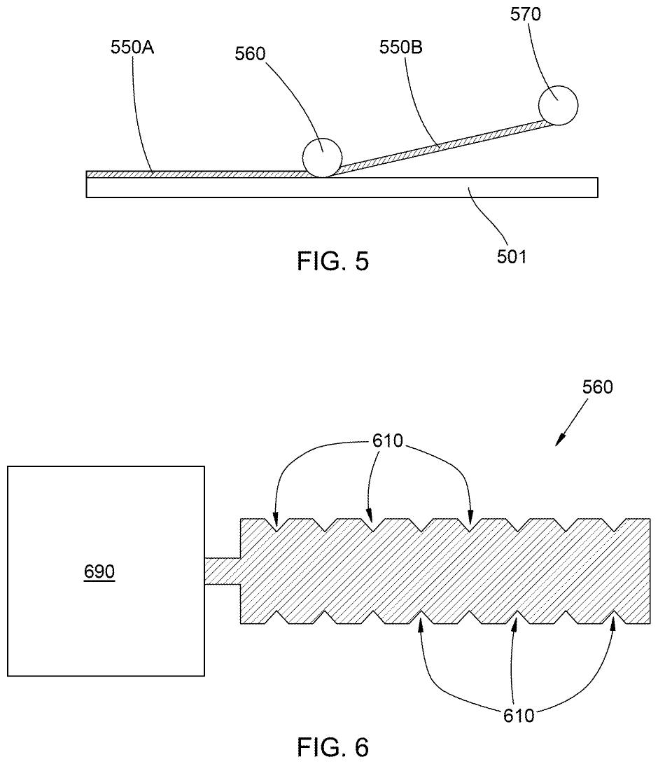

FIG. 5 shows a side view of the roller apparatus used to bond wires to the doped regions of solar cells. In FIG. 5, a metal wire comprising sections 550A and 550B is being bonded to a doped region (not shown) of solar cell 501. Portion 550A of the metal wire has already been bonded to solar cell 501 whereas portion 550B of the wire has not yet been bonded. As solar cell 501 moves to the left in FIG. 5, metal wire 550B from wire spool 570 is guided to solar cell 501 and pressed onto a doped region of solar cell 501 by roller 560. A download force is exerted by the roller in the range of 20 N to 80 N per wire being bonded. In one embodiment, the force exerted is about 400 N with 8 wires being simultaneously bonded, i.e. a force of 50 N per wire. In another embodiment, the force exerted by the roller is about 9,600 N with 194 wires being simultaneously bonded to the solar cell, i.e. a force of 49 N per wire bonded. The roller may also be heated to a temperature in the range of 300° C. to 500° C. For example, for wire bonding, the roller may exert a downward force of 50 N per wire and be heated to about 400° C.

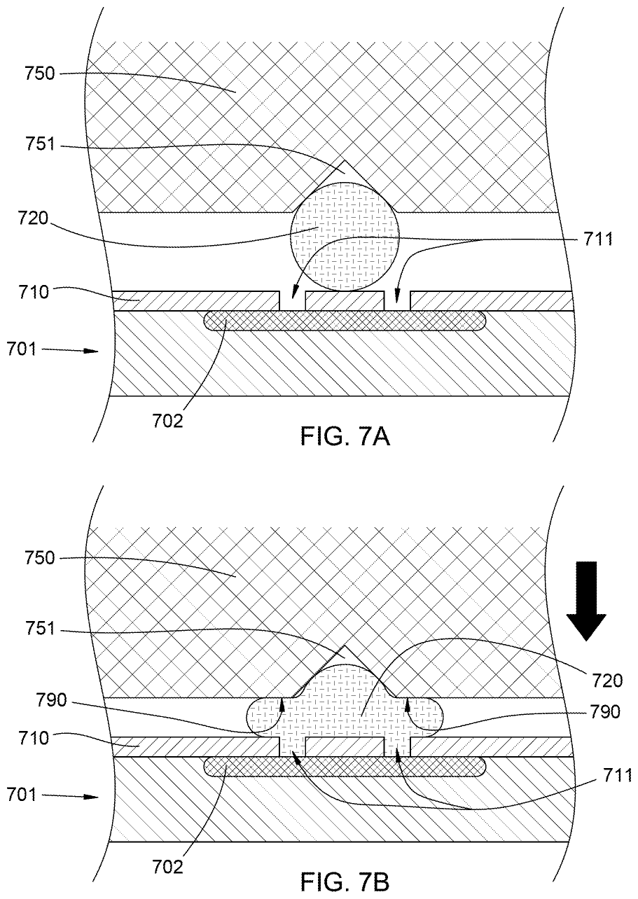

FIG. 6 shows a longitudinal cross-sectional view of roller 560. Roller 560 has a plurality of grooves 610. The shape of the cross-sectional area of the groove may be triangular as shown in FIG. 560. Other cross-sectional shapes are possible, e.g. semi-circular, rectangular, or trapezoidal. Preferably, the cross-sectional shape of the groove has a centering effect on a wire placed within the groove. For example, in a groove with a triangular cross-sectional area, the sloped walls of the groove tend to make a wire placed in the groove move to the center of the groove. In some embodiments, grooves with sloped walls are preferred, where the sloped walls of the groove are configured to guide a wire placed in the groove towards the center of the groove. A semi-circular or trapezoidal shaped groove has a similar wire centering effect. A rectangular shaped groove can also have a wire centering effect if the width of the rectangular groove is less than the width of the wire. If the width of the rectangular groove, i.e. the width of the opening of the rectangular groove, is less than the width of the wire, the edges of the rectangular groove will catch the wire, if the wire is slightly misaligned, and center the wire within the rectangular groove because the shape of the wire is sloped or substantially circular.

The number of grooves in the roller depends on the number of metal wires that need to simultaneously bonded. FIG. 6 shows a roller with eight grooves suitable for use on the solar cell which needs eight bonded wires. For example, if a solar cell had 194 doped regions that required serial connections, then a roller with 194 grooves would be used to simultaneously bond 194 wires to the solar cell. Roller 560 may be turned by attached motor 690.

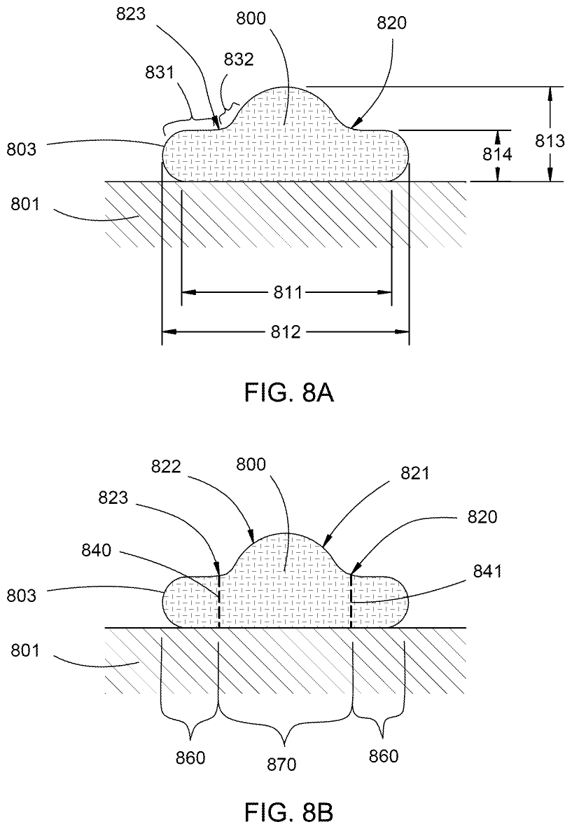

FIG. 7A shows a cross-sectional view of solar cell 701 with wire 720 and roller 750 where no downwards force is applied to the roller. Solar cell 701 contains doped region 702. Solar cell 701 may also have passivation layer 710 which may comprise silicon nitride, aluminum oxide, silicon dioxide, or other materials that provide good surface passivation. Passivation layer 710 has two rows of holes 711 running along the length of doped region 702. The passivation layer may have a plurality of rows of holes running along the length of the doped region. For example, the passivation layer may have 1, 2, 3, 4, or 5 rows of holes of each doped region. Holes 711 may have a variety of sizes, from <10 um width to >40 um width, and holes 711 may have a variety of shapes, including linear, rectangular openings, ovoid, or circular. Holes 711 allow metal wire 720 to directly contact doped region 702. As the number of holes in the passivation layer increases, recombination at the surface of the silicon substrate increases thereby reducing efficiency. But a greater number of holes in the passivation layer increases the metal to semiconductor contact area which may reduce contact resistance and increase efficiency.

As shown in FIG. 7A, the shape of groove 751 with its sloped walls can guide wire 720 to the center of groove 751. This in turn helps align wire 720 to doped region 702 and to holes 711. As can be appreciated, if wire 720 is not properly aligned with doped region 702 and holes 711, then upon bonding wire 720 to solar cell 701, wire 720 will not contact doped region 702 resulting in bad metal contact and loss of solar cell efficiency.

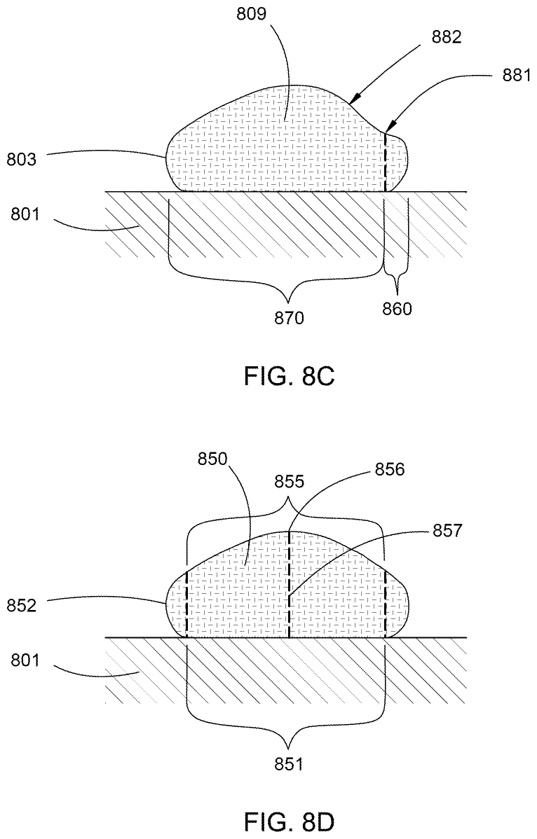

FIG. 7B shows a cross-sectional view of solar cell 701 with wire 720 and roller 750 where downwards force is applied on the roller. The downward force of the roller deforms and flattens wire 720 so that wire 720 contacts the doped region 702 through holes 711 in passivation layer 710. As shown in FIG. 7B, roller 750 is configured so that when downward force is applied, wire 720 is deformed and squeezed between a non-groove portion 790 of roller 750 and solar cell 701. This gives the metal wire a head and shoulder shape. The sloped walls of groove 751 result in a curved head shape while squeezing wire 720 between the non-groove portion of the roller and solar cell forms the shoulders of wire 720. While FIG. 7B shows an embodiment where wire 720 is squeezed to form a shoulder, in an alternate embodiment, groove 751 is wide enough so that wire 720 is not squeezed between the non-groove portion of the roller and solar cell. In such a case, wire shoulders are not formed as depicted in FIG. 8D.

Squeezing wire 720 between the non-groove portion of the roller and solar cell may be advantageous because it may widen the footprint of the wire and therefore increase the contact area of the wire with the solar cell. If the solar cell did not have a passivation layer, an increase in contact area is advantageous because it would increase the area of metal contact with the doped region and thereby decrease the series resistance of the solar cell. If the solar cell does have a passivation layer, an increase in contact area may be advantageous because it decreases the precision needed for wire placement. For example, if the contact area were smaller, a slightly misplaced wire would potentially not cover hole 711 when bonded and therefore not form the necessary contact with doped region 702.

There exists a need for greater precision in wire placement as a greater number of wires are used to connect solar cells. As a greater number of wires are used, the wire pitch, i.e. the distance between adjacent wires, becomes smaller. Also, the greater number of wires used, the smaller the width of a doped region and the distance between doped regions becomes smaller. This decrease in wire pitch, doped region width, and doped region spacing necessitates finer control and greater precision in wire placement. Roller 750 allows for greater precision in wire placement as well as a greater tolerance for inaccurate wire placement. The groove of the roller provides a centering effect, as discussed above. This centering effect of the groove provides greater precision in wire placement. Also, use of the roller may result in a wider wire footprint which provides a greater tolerance for inaccurate wire placement and provides for less resistance in the case where no passivation layer is present.

FIG. 8A shows the cross-sectional view of metal wire 800 bonded to solar cell 801 using the roller discussed above. FIG. 8A shows wire 800 has a cross-sectional area is taken perpendicular to the length of the wire and that this cross-section area has a perimeter 803. Perimeter 803 of the cross-sectional area has a footprint length 811, which is the length of perimeter 803 contacting solar cell 801 or the passivation layer of the solar cell (not shown). The portion of the perimeter spanning footprint length 811 is substantially straight. The cross-sectional area of wire 800 has peak height 813, which is the maximum height of wire 800 measured from length 811. The cross-sectional area also has width 812 parallel to length 811. On the side opposite of length 811, perimeter 803 has a head and shoulder shape. Representing perimeter 803 as a smooth curve, the transition between the shoulder portion and the head portion of perimeter 803 occurs at inflection points 820 and 823. An inflection point is a point of a curve at which the sign of the curvature (i.e. the concavity) changes. For example, at inflection point 823, the concavity of perimeter 803 changes from concave (concave downward) in section 831 to convex (concave upward) in section 832.

The perimeters having two shoulders will have four inflection points. FIG. 8B shows the four inflection points: 820, 821, 822, and 823 of perimeter 803. But the transition from the shoulder portion to the head portion occurs only at the inflection points closest to length 811, i.e. at inflection points 820 and 823 only. Inflection points 820 and 823 are located on opposite sides of the wire. Shoulder height 814 of the wire (shown in FIG. 8A) is the height of inflection point 820 from length 811. A shoulder height may also be taken from inflection point 823. In the preferred embodiment, the shoulder height of one shoulder is substantially the same as the shoulder height of the other shoulder. The cross-sectional area of the wire has head portion 870 and shoulder portions 860 as shown in FIG. 8B. Lines 840 and 841 (which are perpendicular to length 811) separate the head portion from the shoulder portions. The position of lines 840 and 841 are defined by the position of inflection points 820 and 823. The perimeter of head portion 870 in contact with solar cell 801 is substantially straight, whereas the perimeter of the head portion 870 opposite solar cell 801 comprises a curved portion.

FIG. 8C shows wire 809 bonded to solar cell 801. Wire 809 has head portion 870 and only one shoulder portion 860. Perimeter 803 of the cross-sectional area of wire 809 has only two inflection points 881 and 882. But the transition from shoulder to head occurs only at the inflection point closest to length 811, i.e. at inflection point 881 only.

FIG. 8D shows wire 850 having no shoulders and therefore no inflection points on cross-sectional perimeter 852. The cross-sectional area of wire 850 has a dome shape. Perimeter 852 of the dome-shaped wire 850 comprises a substantially straight portion 851 that is in contact with solar cell 801 and a curved portion 855 opposite straight portion 851. In some embodiments, perimeter 852 also has a center portion 856 which is curved, center portion 856 is located at midline 857 of the cross-sectional area and opposite straight portion 851. Wire 850 with its dome shape and without shoulders may be formed with a roller groove having sloped walls when the width of the groove is wide enough so that wire 850 is not squeezed between the non-groove portion of the roller and solar cell.

To obtain a wire with a head and shoulder shape, the width of the groove is precisely configured so that when bonding the wire to the solar cell, the wire material is deformed and squeezed into the gap between non-groove portion of the roller and solar cell. If the width of the groove is too great, the wire material will be wholly contained within the groove when pressure is applied, and the wire material will not be forced into the gap between non-groove portion of the roller and solar cell and the resulting wire will not have a head-shoulder shape. For example, FIG. 8D shows a bonded wire where no shoulders are formed. Further, if the width of the groove is too small, then the groove may lose its ability to properly center the wire within the groove, which will result in a lack of wire placement precision. A proper groove depth must also be used to obtain a wire with a head-shoulder shape. For example, for a wire having a 250 micron diameter, a triangular shaped groove having a 150 micron base (the groove width at the opening) and a 50 micron depth (height of the triangle) can be used to obtain a wire having a head and shoulder shape.

Using roller 560 coupled with thermocompression to bond a wire to a solar cell results in a continuous bond for a substantial length of the solar cell. For example, metal wire 205 in FIG. 2 would have a continuous head and shoulder cross-sectional shape for the majority of the length of solar cell 201. Between solar cells 201 and 202, wire 205 would assume its original undeformed shape, e.g. a wire with a substantially circular cross-sectional area. For the portion of wire 205 contacting solar cell 202, wire 205 would again assume a continuous head and shoulder cross-sectional shape for the majority of the length of solar cell 202.

An important metric in solar cell or solar module manufacturing is cost. Solar cells need to be cost effective to remain competitive in the market and therefore cost reduction is a key focus of the industry. Use of the roller described in this application to bond wires provides for greater cost effectiveness. The greater precision in wire placement achieved by the roller groove shape and the greater tolerance for wire misplacement provided by a longer wire footprint length allows greater manufacturing throughput. Using the roller of this application, bonding speeds of greater than 120 millimeter per second can be achieved. Higher bonding speeds leads to greater cost effectiveness since more solar cells can be interconnected per unit of time.

A wire bonded to the solar cell according to the method of this application may be made of copper or aluminum. Aluminum wires may be preferred due to aluminum having low cost but still being an excellent conductor. Using the method of this application, aluminum wires may be bonded to solar cells in their bulk form, i.e. off-the-shelf wires that don't need further treatment such as electroplating. Use of bulk form wires further decreases the costs of solar cell manufacturing.

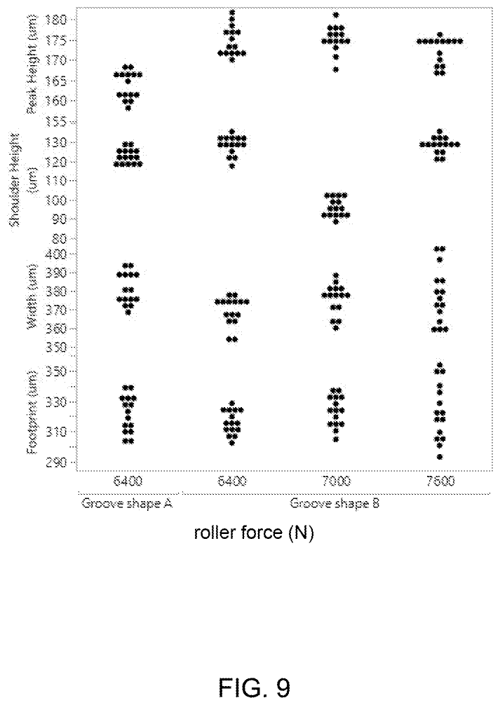

FIG. 9 is a dot plot showing different measurements of footprint length, wire width, shoulder height, and peak height of wires bonded to solar cells. Measurements for two different rollers are shown with each roller having a different groove shape: groove shape A and groove shape B. The rollers applied 6,400 N, 6,400 N, 7000 N, and 7600 N of force to bond 194 wires simultaneously, which is about 33 N, 33 N, 36 N, and 40 N of force per wire respectively. As shown in FIG. 9, the footprint length of the wire ranges from about 290 microns to about 355 microns. The footprint length may be from 200 microns to 500 microns in length. The width of the wire ranges from about 355 microns to about 400 microns. The shoulder height of the wire ranges from about 90 microns to about 140 microns. The peak height of the wire ranges from about 157 microns to about 183 microns. In all cases, the shoulder height of the wire is less than the peak height of the wire.

This disclosure is illustrative and not limiting. Further modifications will be apparent to one skilled in the art in light of this disclosure and are intended to fall within the scope of the appended claims. For example, where methods and steps described above indicate certain events occurring in certain order, those of ordinary skill in the art will recognize that the ordering of certain steps may be modified, and that some steps may be omitted or additional steps added, and that such modifications are in accordance with the variations of the invention.

What is claimed is:

1. A string of solar cells comprising:
at least a first and second solar cells electrically connected in series, each solar cell comprising:
a silicon semiconductor substrate,
an n-type doped region, and
a p-type doped region; and
a conductive wire in contact with the n-type doped region of the first solar cell and in contact with the p-type doped region of the second solar cell,
the conductive wire at a point of contact with the n-type doped region of the first solar cell having a cross-sectional area perpendicular to a length of the conductive wire, a perimeter of the cross-sectional area having an inflection point.

2. The string of solar cells of claim 1, wherein the conductive wire at a point of contact with the p-type doped region of the second solar cell has a second cross-sectional area perpendicular to the length of the conductive wire, a perimeter of the second cross-sectional area has an inflection point.

3. The string of solar cells of claim 1, wherein the cross-sectional area has a cross-sectional shape, and the conductive wire has substantially the same cross-sectional shape along a majority of a length of the first solar cell.

4. The string of solar cells of claim 1, wherein the cross-sectional area has a head and shoulder shape.

5. The string of solar cells of claim 1, wherein the perimeter of the cross-sectional area has a footprint length greater than 200 micrometers and less than 500 micrometers.

6. The string of solar cells of claim 1, wherein the perimeter of the cross-sectional area has a footprint length and a line from the footprint length to the inflection point on the perimeter delineates a shoulder portion of the cross-sectional area, the shoulder portion having a side opposite the footprint length that is substantially flat and parallel to the footprint length.

7. The string of solar cells of claim 1, wherein the perimeter of the cross-sectional area has a footprint length and the cross-sectional area has a width, and wherein the width is greater than the footprint length.

8. The string of solar cells of claim 1, comprising a passivation layer coating the silicon semiconductor substrate, the passivation layer comprising a hole, and wherein the contact of the conductive wire with the n-type doped region is through the hole in the passivation layer.

9. The string of solar cells of claim 1, wherein the conductive wire comprises aluminum or an aluminum alloy.

10. The string of solar cells of claim 1, wherein the perimeter has 2 inflection points.

11. The string of solar cells of claim 1, wherein the perimeter has 4 inflection points.

12. A string of solar cells comprising:
at least a first and second solar cells electrically connected in series, each solar cell comprising:
a silicon semiconductor substrate,
an n-type doped region, and
a p-type doped region; and
a conductive wire in contact with the n-type doped region of the first solar cell and in contact with the p-type doped region of the second solar cell,
the conductive wire at a point of contact with the n-type doped region of the first solar cell having a cross-sectional area perpendicular to a length of the conductive wire, a perimeter of the cross-sectional area having a substantially straight portion adjacent to first solar cell and a curved portion opposite the substantially straight portion.

13. The string of solar cells of claim 12, wherein the perimeter comprises a curved portion located at the midline of the cross-sectional area and opposite the substantially straight portion.

14. The string of solar cells of claim 12, wherein the wire comprises aluminum or an aluminum alloy.

15. The string of solar cells of claim 12, wherein the cross-sectional area has a cross-sectional shape, and the conductive wire has substantially the same cross-sectional shape along a majority of a length of the first solar cell.

16. A method of fabricating a string of solar cells, the method comprising:
positioning at least two solar cells adjacent to one another such that a doped region of a first solar cell is aligned with a doped region of the second solar cell,
providing a roller comprising a groove,
placing a wire within the groove, the groove having either sloped walls or a rectangular shape where a width of the rectangular shape is less than a width of the wire,
bonding the wire within the groove to the doped region of the first solar cell by applying a force onto the roller, dimensions of the groove are configured so that when the force is applied, a perimeter of a cross-sectional area of the bonded wire either has an inflection point or has a substantially straight portion adjacent to first solar cell and a curved portion opposite the substantially straight portion, and
bonding the wire within the groove to the doped region of the second solar cell.

17. The method of claim 16, wherein bonding the wire comprises rolling the roller along the first and second solar cells.

18. The method of claim 16, wherein bonding the wire comprises applying heat so that the temperature of the roller is between 300° C. to 500° C.

19. The method of claim 16, wherein bonding the wire comprises deforming the cross-sectional shape of the wire, the deformed wire having a head and shoulder shape.

20. The method of claim 16, wherein
the first solar cell comprises a plurality of doped regions,
the roller comprises a plurality of grooves,
placing a wire comprises placing a plurality of wires within the plurality of grooves, and
bonding the wire within the groove to the doped region of the first solar cell comprises simultaneously bonding the plurality of wires within the grooves to a plurality of doped regions of the first solar cell.
